(19) United States
(12) Patent Application Publication
(10) Pub. No.: US 2020/0243733 A1
(43) Pub. Date: Jul. 30, 2020

(54) LIGHT-EMITTING DEVICE AND METHOD FOR MANUFACTURING SAME

(71) Applicants: CITIZEN ELECTRONICS CO., LTD., Fujiyoshida-shi, Yamanashi (JP); CITIZEN WATCH CO., LTD., Tokyo (JP)

(72) Inventors: Sadato Imai, Minamitsuru-gun, Yamanashi (JP); Kohsuke Kashitani, Fujiyoshida-shi, Yamanasshi (JP); Teruhiko Hodohara, Fujiyoshida-shi, Yamanashi (JP)

(73) Assignees: CITIZEN ELECTRONICS CO., LTD., Fujiyoshida-shi, Yamanashi (JP); CITIZEN WATCH CO., LTD., Tokyo (JP)

(21) Appl. No.: 15/754,930

(22) PCT Filed: Jun. 17, 2016
(86) PCT No.: PCT/JP2016/068183

§ 371 Date: Feb. 23, 2018

(30) Foreign Application Priority Data
Aug. 31, 2015 (JP) 2015-171086
Aug. 31, 2015 (JP) 2015-171115
Aug. 31, 2015 (JP) 2015-171124
Aug. 31, 2015 (JP) 2015-171133
Aug. 31, 2015 (JP) 2015-171139
Aug. 31, 2015 (JP) 2015-171150
Aug. 31, 2015 (JP) 2015-171208
Aug. 31, 2015 (JP) 2015-171331

(51) Int. Cl. H01L 33/58; H01L 25/075; H01L 25/16; H01L 33/50; H01L 33/56; H01L 33/62; H01L 33/64

(52) U.S. Cl. CPC H01L 33/58; H01L 25/0753; H01L 25/167; H01L 33/502; H01L 33/56; H01L 2933/0075; H01L 33/642; H01L 2933/0041; H01L 2933/005; H01L 2933/0058; H01L 2933/0066; H01L 33/62

(57) ABSTRACT

It is made possible to use a lens array including common lenses as a lens array that collects beams of light from light-emitting units, regardless of the number of light-emitting elements included in each light-emitting unit, thereby reducing the manufacturing cost of a light-emitting device. The light-emitting device includes a substrate, light-emitting units arranged on the substrate, and a lens array including lenses provided corresponding to the light-emitting units, respectively, to collect beams of emission light from the respective light-emitting units, the lens array being arranged on the light-emitting units. Each of the light-emitting units has light-emitting elements that are mounted on the substrate in a lattice pattern and are series-parallel connected to one another in a mount region whose shape is common in the light-emitting units so as to include a predetermined number of series connections and a predetermined number of parallel connections which are set for the light-emitting unit.

### CROSS REFERENCE TO RELATED APPLICATIONS

This is the U.S. National Phase application of PCT/JP2016/068183, filed Jun. 17, 2016, which claims priority to Japanese Patent Application No. 2015-171086, filed Aug. 31, 2015, Japanese Patent Application No. 2015-171115, filed Aug. 31, 2015, Japanese Patent Application No. 2015-171124, filed Aug. 31, 2015, Japanese Patent Application No. 2015-171133, filed Aug. 31, 2015, Japanese Patent Application No. 2015-171139, filed Aug. 31, 2015, Japanese Patent Application No. 2015-171150, filed Aug. 31, 2015, Japanese Patent Application No. 2015-171208, filed Aug. 31, 2015 and Japanese Patent Application No. 2015-171331, filed Aug. 31, 2015, the disclosures of these applications being incorporated herein by reference in their entireties for all purposes.

### TECHNICAL FIELD OF THE INVENTION

The present invention relates to a light-emitting device and a manufacturing method thereof.

### BACKGROUND OF THE INVENTION

A chip-on-board (COB) light-emitting device in which light-emitting elements, such as light-emitting diode (LED) elements, are mounted on a general-purpose substrate, such as a ceramic substrate or a metal substrate, is known. In such a light-emitting device, by sealing the LED elements with a translucent resin containing a phosphor, and by mixing light from the LED elements and light obtained by exciting the phosphor by the light from the LED elements, white light or the like can be obtained depending on the intended use.

For example, Patent literature 1 describes a light-emitting diode including a high thermal conductive heat radiation base having a mounting surface for die bonding, a circuit substrate mounted on the heat radiation base and having a hole through which a part of the mounting surface is exposed and a protruding part that projects outwardly from the outer periphery of the heat radiation base, light-emitting elements mounted on the mounting surface through the hole, and a translucent resin body that seals the upper side of the light-emitting elements, wherein through-holes that are electrically connected to the light-emitting elements are formed in the outer periphery of the protruding part, and external connection electrodes are provided at the upper surface and the lower surface of the through-holes.

In addition, Patent literature 2 describes an LED package having a cavity in which a concave part is formed, a convex heat slug (pedestal part) attached to the cavity so as to penetrate the bottom of the concave part, a submount substrate mounted on the heat slug, LED chips arranged on the submount substrate, a lead frame electrically connected to the respective LED chips, a phosphor layer enclosing the respective LED chips, and a lens formed by a silicone resin filled in the concave part.

In addition, a lighting apparatus whose light quantity is increased by integrally arranging multiple LEDs is known. For example, Patent literature 3 describes an LED lighting apparatus having LEDs, a substrate on which the LEDs are mounted, and a lens array in which lens elements for collecting or diverging radiation light emitted from the LEDs are integrally configured.

### PATENT LITERATURE

Patent literature 1: Japanese Unexamined Patent Publication (Kokai) No. 2006-005290
Patent literature 2: Japanese Unexamined Patent Publication (Kokai) No. 2010-170945
Patent literature 3: Japanese Unexamined Patent Publication (Kokai) No. 2012-042670

### SUMMARY OF INVENTION

In order to obtain parallel light having high light quantity, it is desirable to manufacture a light-emitting device in which light-emitting units each including light-emitting elements, such as LED elements, are formed on one common substrate and emission light from each light-emitting unit is collected by a lens corresponding to the light-emitting unit to be emitted. In such a light-emitting device, the number of the LED elements included in one light-emitting unit may be changed in each light-emitting unit such that the forward voltage of the LED elements as the whole of the device falls within a range that a driver used can drive. However, when the number of the elements is changed in each light-emitting unit, a light-emitting diameter is also changed; therefore, in order to optimize the light collecting efficiency, the size of the lens also needs to be adjusted in each light-emitting unit according to the light-emitting diameter. In this case, a plurality of different lens arrays need to be prepared in manufacturing the light-emitting device, thereby increasing the manufacturing cost.

In addition, when a light-emitting device in which light-emitting units are formed on one common substrate and each light-emitting unit includes LED elements is manufactured, a driver designed for driving a light-emitting device using certain LED elements is sometimes desired to be also used for a light-emitting device using other LED elements, in order to reduce the manufacturing cost, for example. However, when LED elements having different forward voltages are used, the forward voltage of the whole of the device can be drastically changed compared to the former light-emitting device, and thus, the light-emitting device using other LED elements may not be driven by the common driver.

In addition, when a light-emitting device having more than one COB light-emitting units in each of which light-emitting elements are mounted on one metal substrate is manufactured, the number of the elements included in the whole of the light-emitting device is increased, and the amount of heat generated during driving is also increased, and thus, an idea of promoting heat radiation is necessary.

In addition, in a light-emitting device in which light-emitting units are formed on one common substrate, it may be desired not only to light the light-emitting units at one time but also to light each light-emitting unit separately to check operation thereof. For this purpose, a plurality of groups of inspection terminals respectively corresponding to the light-emitting units may be provided on the common substrate; but when there are variations in the arrangement of the inspection terminals in each light-emitting unit, the step of the operation check is complicated, and erroneous measurement may occur.

In addition, when a light-emitting device in which beams of emission light from light-emitting units each including series-parallel connected LED elements are collected by a lens array to be emitted is manufactured, it is conceivable that the density of the light-emitting units on a common substrate is increased by changing a light-emitting diameter according to the number of the LED elements in a light-emitting unit and by combining light-emitting units having different light-emitting diameters. However, in such a light-emitting device, the light-emitting units on the substrate and lenses in the lens array are in one-to-one correspondence, and thus, the number of the light-emitting units that can be formed on the common substrate is also limited by the size of each lens.

In addition, a light-emitting device in which light-emitting units are formed on one common substrate and emission light from each light-emitting unit is collected by a lens corresponding to the light-emitting unit to be emitted is manufactured, a relative position between the light-emitting units and a lens array including lenses corresponding thereto needs to be adjusted at the time of manufacture, in order to improve the emission efficiency from the light-emitting units through the lenses. However, since this step is troublesome, it is desirable to make position adjustment between the light-emitting units and the lenses more efficient by some sort of idea.

In addition, in the light-emitting device in which light-emitting units are formed on one common substrate and emission light from each light-emitting unit is collected by a lens corresponding to the light-emitting unit to be emitted, when light-emitting elements are mounted on each light-emitting unit, the number of the elements included in the whole of the light-emitting device is increased, and the amount of heat generated during driving is also increased. Thus, expansion of the common substrate and the lenses due to the heat cannot be ignored, and shift occurs in the relative position of both, and thus, the emission efficiency through the lenses may be decreased.

It is an object of the present invention to make it possible to use a lens array including common lenses as a lens array that collects beams of light from light-emitting units, regardless of the number of light-emitting elements included in each light-emitting unit, thereby reducing the manufacturing cost of a light-emitting device.

It is another object of the present invention to make it possible to drive a light-emitting device in which light-emitting units each including LED elements are formed on a common substrate by a common driver, regardless of a forward voltage of each LED element.

It is another object of the present invention to, when light-emitting units each including light-emitting elements are formed on a common metal substrate to form one light-emitting device, promote releasing, to the outside of the device, heat transferred from the respective light-emitting elements to the metal substrate.

It is another object of the present invention to make operation check of each light-emitting unit easy, at the time of manufacture of a light-emitting device in which light-emitting units are formed on a common substrate, thereby lowering the occurrence frequency of erroneous measurement.

It is another object of the present invention to arrange more light-emitting units on a common substrate in a light-emitting device that emits light through a lens array, thereby increasing the emission light quantity.

It is another object of the present invention to simplify the step of adjusting a relative position between light-emitting units and lenses at the time of manufacture of a light-emitting device in which beams of emission light from the light-emitting units are collected by the lenses corresponding to the respective light-emitting units to be emitted.

It is another object of the present invention to improve the emission efficiency from light-emitting units through lenses when thermal expansion occurs in a common substrate and the lenses by driving a light-emitting device.

Provided is a light-emitting device including a substrate, light-emitting units arranged on the substrate, and a lens array including lenses provided corresponding to the light-emitting units, respectively, to collect beams of emission light from the respective light-emitting units, the lens array being arranged on the light-emitting units, wherein each of the light-emitting units has light-emitting elements that are mounted on the substrate in a lattice pattern and are series-parallel connected to one another in a mount region whose shape and size are common in the light-emitting units so as to include a predetermined number of series connections and a predetermined number of parallel connections which are set for the light-emitting unit.

In addition, provided is a light-emitting device including a substrate, light-emitting units arranged on the substrate, and a driver that drives the light-emitting units, wherein each of the light-emitting units has LED elements that are divided into a plurality of columns connected in parallel with one another and are connected in series with one another in each of the columns, and the number of LED elements connected in series in each of the light-emitting units is set such that a sum of forward voltages of LED elements connected in series in the whole of the light-emitting units falls within a range of a voltage that the driver can drive.

In addition, provided is a light-emitting device including a metal substrate having an opening, and light-emitting units uniformly arranged on the metal substrate so as to surround the opening, wherein each of the light-emitting units has light-emitting elements mounted on the metal substrate, a sealing frame that surrounds the light-emitting elements, and a sealing resin that is filled in a region surrounded by the sealing frame on the metal substrate to seal the light-emitting elements.

In addition, provided is a light-emitting device including a substrate, light-emitting units arranged on the substrate, a lens array including lenses provided corresponding to the light-emitting units, respectively, to collect beams of emission light from the respective light-emitting units, the lens array being arranged on the light-emitting units, and a plurality of groups of inspection terminals, each of which is formed corresponding to each of the light-emitting units at positions on the substrate in a diameter of a principal surface of one of the lenses corresponding to the light-emitting unit, the positions being separated with an interval common in the light-emitting units.

In addition, provided is a light-emitting device including a substrate, light-emitting units arranged on the substrate, and a lens array including lenses provided corresponding to the light-emitting units, respectively, to collect beams of emission light from the respective light-emitting units, the lens array being arranged on the light-emitting units, wherein each of the light-emitting units has LED elements that mounted on the substrate at the same mounting density as those in the light-emitting units, and are series-parallel connected to one another so as to include a predetermined number of series connections and a predetermined number of parallel connections which are set for the light-emitting unit, and each of the lenses has a larger size as the number of the LED elements included in a light-emitting unit corresponding to the lens is larger.

In addition, provided is a light-emitting device including a substrate, light-emitting units arranged on the substrate, and a lens array including lenses provided corresponding to the light-emitting units, respectively, to collect beams of emission light from the respective light-emitting units, the lens array being arranged on the light-emitting units, wherein each of the light-emitting units has light-emitting elements that are divided into a plurality of columns connected in parallel with one another and are connected in series with one another in each of the columns so as to include a predetermined number of series connections which is set for the light-emitting unit, and the light-emitting elements have a smaller size in a light-emitting unit in which the number of light-emitting elements connected in series is larger.

In addition, provided is a manufacturing method of a light-emitting device, including the steps of forming light-emitting units by mounting a plurality of groups of light-emitting elements on a substrate in which openings are formed, based on positions of the openings, arranging a lens array including support units and lenses arranged according to arrangement positions of the light-emitting units on the substrate, on the light-emitting units, and positioning the substrate and the lens array by fitting the support units into the openings.

In addition, provided is a manufacturing method of a light-emitting device, including the steps of forming light-emitting units by mounting a plurality of groups of light-emitting elements on a substrate, arranging a lens array including lenses arranged according to arrangement positions of the light-emitting units, on the light-emitting units, and positioning the substrate and the lens array by shifting the light-emitting units and the lenses from one another by a distance having a size according to thermal expansion coefficients of the substrate and the lens array such that positions of the light-emitting units relatively conform to positions of the lenses when the substrate and the lens array thermally expand by lighting the light-emitting units.

In addition, provided is a light-emitting device including a substrate, light-emitting units arranged on the substrate, and a lens array including lenses provided corresponding to the light-emitting units, respectively, to collect beams of emission light from the respective light-emitting units, the lens array being arranged on the light-emitting units, wherein each of the light-emitting units has light-emitting elements that are mounted on the substrate in a lattice pattern and are series-parallel connected to one another in a mount region whose shape is common in the light-emitting units so as to include a predetermined number of series connections and a predetermined number of parallel connections which are set for the light-emitting unit.

Preferably, in the above light-emitting device, in each of the light-emitting units, the light-emitting elements are mounted in a mount region whose shape and size are common in the light-emitting units at a mounting density different in each light-emitting unit.

Preferably, in the above light-emitting device, in the light-emitting units, a light-emitting unit in which the number of series connections is smaller has LED elements having higher forward voltages as the light-emitting elements.

Preferably, in the above light-emitting device, the mount region has a rectangular shape, and, in each of the light-emitting units, the light-emitting elements are mounted on at least four corners of the rectangular shape.

Preferably, in the above light-emitting device, each of the light-emitting units has LED elements mounted on the substrate and electrically connected to one another by wires, as the light-emitting elements, and further has a sealing resin that contains a phosphor and is filled on the substrate to seal the LED elements.

Preferably, in the above light-emitting device, each of the light-emitting units has LED packages flip-chip mounted on the substrate, as the light-emitting elements, and each of the LED packages has an LED element and a resin layer that contains a phosphor and covers an upper surface and side surfaces of the LED element.

Preferably, the above light-emitting device further includes a driver that drives the light-emitting units, and the light-emitting elements are LED elements, and the number of LED elements connected in series in each of the light-emitting units is set such that a sum of forward voltages of LED elements connected in series in the whole of the light-emitting units falls within a range of a voltage that the driver can drive.

Preferably, in the above light-emitting device, the light-emitting units are connected in series with the driver.

Preferably, in the above light-emitting device, the light-emitting units are divided into a plurality of groups that are connected in parallel with the driver, and light-emitting units included in each of the groups are connected in series with one another.

Preferably, in the above light-emitting device, the substrate is a metal substrate having an opening, the light-emitting units are uniformly arranged on the metal substrate so as to surround the opening, and each of the light-emitting units further has a sealing frame that surrounds the light-emitting elements, and a sealing resin that is filled in a region surrounded by the sealing frame on the metal substrate to seal the light-emitting elements.

Preferably, the above light-emitting device further includes a heatsink that is attached to a rear surface of the metal substrate and radiates heat generated by the light-emitting units.

Preferably, in the above light-emitting device, a diameter of the opening is larger than arrangement intervals of the light-emitting units.

Preferably, in the above light-emitting device, the lenses are not arranged above the opening.

Preferably, the above light-emitting device further includes a plurality of groups of inspection terminals, each of which is formed corresponding to each of the light-emitting units at positions on the substrate in a diameter of a principal surface of one of the lenses corresponding to the light-emitting unit, the positions being separated with an interval common in the light-emitting units.

Preferably, in the above light-emitting device, the plurality of groups of inspection terminals are pairs of two terminals, and are arranged at a common angle with respect to a side of the substrate.

Preferably, in the above light-emitting device, each of the light-emitting units has LED elements mounted at the same mounting density as those in the light-emitting units, as the light-emitting elements, and each of the lenses has a larger size as the number of the LED elements included in a light-emitting unit corresponding to the lens is larger.

Preferably, in the above light-emitting device, the light-emitting units are configured by first light-emitting units each having LED elements that are series-parallel connected to one another so as to include a first number of series connections and a first number of parallel connections, and second light-emitting units each having LED elements that are series-parallel connected to one another so as to include a second number of series connections smaller than the first number of series connections and a second number of parallel connections smaller than the first number of parallel connections, and the first light-emitting units and the second light-emitting units are alternately arranged on the substrate.

Preferably, in the above light-emitting device, the light-emitting elements have a smaller size in a light-emitting unit in which the number of light-emitting elements connected in series is larger.

Preferably, in the above light-emitting device, areas of light-emitting regions of the light-emitting units are equal to one another.

In addition, provided is a manufacturing method of a light-emitting device, including the steps of forming light-emitting units by mounting a plurality of groups of light-emitting elements on a substrate, and arranging a lens array including lenses arranged according to arrangement positions of the light-emitting units, on the light-emitting units, wherein, in the forming step, in each of the light-emitting units, light-emitting elements whose number is set for the light-emitting unit are mounted in a lattice pattern in a mount region whose shape is common in the light-emitting units, and the light-emitting elements are series-parallel connected to one another so as to include a predetermined number of series connections and a predetermined number of parallel connections which are set for the light-emitting unit.

Preferably, in the forming step of the above manufacturing method, the light-emitting units are formed by mounting the plurality of groups of light-emitting elements on a substrate in which openings are formed, based on positions of the openings, in the arranging step, a lens array having support units is arranged as the lens array, and the manufacturing method further includes the step of positioning the substrate and the lens array by fitting the support units into the openings.

Preferably, in the above manufacturing method, the openings are positioning holes formed on a diagonal line of the substrate, and the support units are columnar members provided on the lens array according to the positions of the openings.

Preferably, in the above manufacturing method, diameters along the diagonal line of the positioning holes become larger with increasing a distance from one end part of the diagonal line, and, in the positioning step, the support units are fixed with respect to the openings such that a relative position between the light-emitting units and the lenses along the diagonal line can be changed in accordance with thermal expansion and thermal contraction.

Preferably, the above manufacturing method further includes the step of sealing the plurality of groups of light-emitting elements for each light-emitting unit by filling a resin in each of the light-emitting units.

Preferably, the above manufacturing method further includes the step of arranging sealing frames that respectively surround the plurality of groups of light-emitting elements on the substrate, based on the positions of the openings, and in the sealing step, the resin is filled in respective regions surrounded by the sealing frames on the substrate.

Preferably, the above manufacturing method further includes the step of positioning the substrate and the lens array by shifting the light-emitting units and the lenses from one another by a distance having a size according to thermal expansion coefficients of the substrate and the lens array such that positions of the light-emitting units relatively conform to positions of the lenses when the substrate and the lens array thermally expand by lighting the light-emitting units.

Preferably, in the above manufacturing method, the substrate has a rectangular shape, in the arranging step, end parts of the substrate and the lens array are fixed to a common housing such that a relative position between the light-emitting units and the lenses can be changed in accordance with thermal expansion and thermal contraction, and, in the positioning step, adjacent two sides of the substrate and the end part of the lens array corresponding to the two sides are brought into contact with the housing, so that the substrate and the lens array are positioned.

Preferably, in the forming step of the above manufacturing method, in each of the light-emitting units, LED elements are mounted on the substrate, as the light-emitting elements, the LED elements are electrically connected to one another by wires, and a sealing resin containing a phosphor is filled on the substrate to seal the LED elements.

Preferably, in the forming step of the above manufacturing method, in each of the light-emitting units, LED packages, each of which is configured by covering an upper surface and side surfaces of an LED element with a resin layer containing a phosphor, are flip-chip mounted on the substrate, as the light-emitting elements.

The above light-emitting device makes it possible to use a lens array including common lenses as a lens array that collects beams of light from light-emitting units, regardless of the number of light-emitting elements included in each light-emitting unit, thereby reducing the manufacturing cost of a light-emitting device.

In addition, the above light-emitting device, which is a light-emitting device in which light-emitting units each including LED elements are formed on a common substrate, can be driven by a common driver, regardless of a forward voltage of each LED element.

In addition, the above light-emitting device, in which light-emitting units each including light-emitting elements are formed on a common metal substrate to form one light-emitting device, can promote releasing, to the outside of the device, heat transferred from the respective light-emitting elements to the metal substrate.

In addition, the above light-emitting device can make operation check of each light-emitting unit easy, at the time of manufacture of a light-emitting device in which light-emitting units are formed on a common substrate, thereby lowering the occurrence frequency of erroneous measurement.

In addition, the above light-emitting device makes it possible to arrange more light-emitting units on a common substrate in a light-emitting device that emits light through a lens array, thereby increasing the emission light quantity.

In addition, the above manufacturing method can simplify the step of adjusting a relative position between light-emitting units and lenses at the time of manufacture of a light-emitting device in which beams of emission light from the light-emitting units are collected by the lenses corresponding to the respective light-emitting units to be emitted.

In addition, the above manufacturing method can improve the emission efficiency from light-emitting units through lenses when thermal expansion occurs in a common substrate and the lenses by driving a light-emitting device.

### BRIEF DESCRIPTION OF DRAWINGS

FIG. 1A is a front view of a lighting apparatus 1.

FIG. 1B is a rear view of a lighting apparatus 1.

FIG. 2A is a top view of a light-emitting device 2.

FIG. 2B is a side view of a light-emitting device 2.

FIG. 3 is a top view of the lens array 40.

FIG. 4A is a top view of the light-emitting unit 20.

FIG. 4B is a cross-sectional view of the light-emitting unit 20 along the line IVB-IVB of FIG. 4A. FIG. 4C is a cross-sectional view of the light-emitting unit 20 along the line IVC-IVC of FIG. 4A.

FIG. 5A is a circuit diagram of the whole of the light-emitting device 2.

FIG. 5B is a circuit diagram of the whole of the light-emitting device 2.

FIG. 6 is a top view of the light-emitting unit 20₃.

FIG. 7 is a diagram schematically illustrating the arrangement of the LED elements 30 in the light-emitting device 2.

FIG. 8 is a flowchart illustrating an example of a manufacturing process of the light-emitting device 2.

FIG. 9A is a diagram illustrating an example of a method for fixing the lens array 40 with respect to the substrate 10.

FIG. 9B is a diagram illustrating an example of a method for fixing the lens array 40 with respect to the substrate 10.

FIG. 9C is a diagram illustrating an example of a method for fixing the lens array 40 with respect to the substrate 10.

FIG. 10A is a diagram illustrating an example of a method for positioning the substrate 10 and the lens array 40.

FIG. 10B is a diagram illustrating an example of a method for positioning the substrate 10 and the lens array 40.

FIG. 11A is a top view of a light-emitting device 2A.

FIG. 11B is a side view of a light-emitting device 2A.

FIG. 12A is a top view of the light-emitting unit 20A.

FIG. 12B is a top view of the light-emitting unit 20A.

FIG. 13 is a diagram schematically illustrating the arrangement of the LED elements 30 in a light-emitting device 2B.

FIG. 14A is a top view of a light-emitting device 2C.

FIG. 14B is a top view of a light-emitting unit 20C in the light-emitting device 2C.

FIG. 15 is a diagram schematically illustrating the arrangement of the LED elements 30 in a light-emitting device 2D.

FIG. 16 is a diagram schematically illustrating the arrangement of the LED elements 30 in a light-emitting device 2E.

FIG. 17A is a top view of a light-emitting device 2F.

FIG. 17B is a side view of a light-emitting device 2F.

FIG. 18A is a top view of a light-emitting unit 20G.

FIG. 18B is a cross-sectional view of the light-emitting unit 20G along the line XVIIIB-XVIIIB of FIG. 18A.

### DETAILED DESCRIPTION OF EMBODIMENTS OF THE INVENTION

Hereinafter, with reference to the accompanying drawings, light-emitting devices and manufacturing methods thereof will be explained in detail. However, it should be noted that the present invention is not limited to the drawings or the embodiments described below.

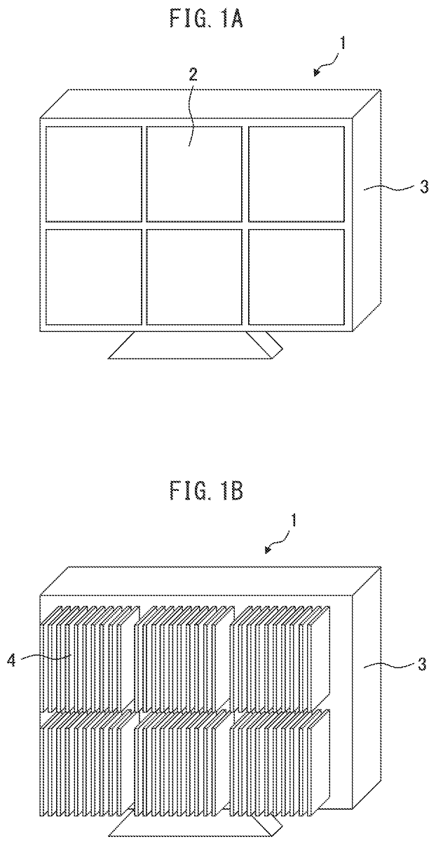

FIG. 1A and FIG. 1B are a front view and a rear view of a lighting apparatus 1. The lighting apparatus 1 is an apparatus that is usable as a flood lamp for lighting, for example, and has a total of six light-emitting devices 2 arranged in two rows and three columns as illustrated in FIG. 1A, as an example. By arranging cases (housings) 3 of the respective light-emitting devices 2 closely, the lighting apparatus 1 is configured as one apparatus. As the number of the light-emitting devices 2 included in one lighting apparatus, there are various examples, such as two, four, and eight or more, in addition to the illustrated one. As illustrated in FIG. 1B, the lighting apparatus 1 has heat radiation fins (heatsinks) 4 for promoting release of heat generated in the light-emitting devices 2, on the rear surface of the cases 3 of the respective light-emitting devices 2.

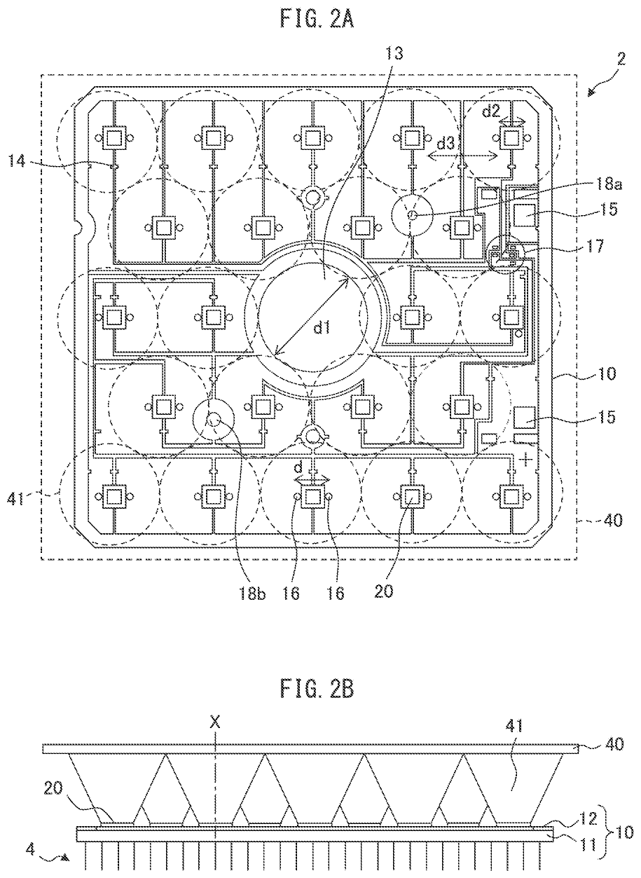

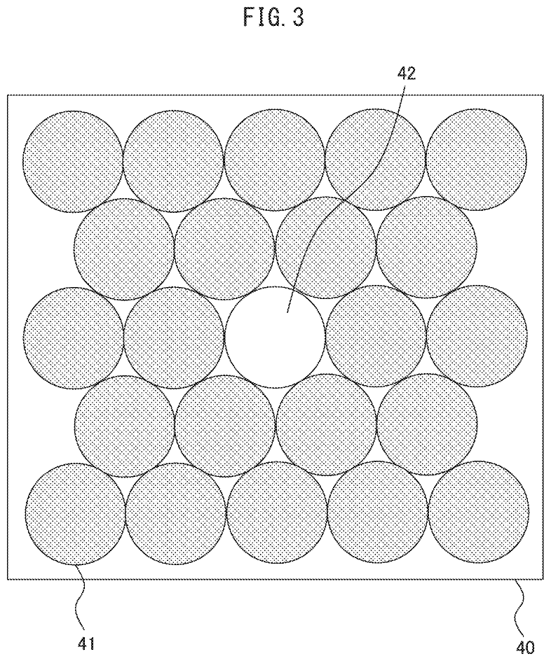

FIG. 2A and FIG. 2B are a top view and a side view of a light-emitting device 2. As illustrated in FIG. 2A and FIG. 2B, the light-emitting device 2 has a substrate 10, light-emitting units 20 formed on the substrate 10, and a lens array 40 arranged on the light-emitting units 20. In addition, as illustrated in FIG. 1B and FIG. 2B, each light-emitting device 2 has a heat radiation fin 4 for radiating heat generated by the light-emitting units 20 on the rear surface of the substrate 10.

The substrate 10 is a substantially rectangular substrate having a circular opening 13 at the center thereof. For example, the length and breadth of the substrate 10 are about 10 cm, respectively, and the thickness of the substrate 10 is about 1 to 2 mm. The substrate 10 is configured by, for example, bonding a circuit substrate 12 onto a metal substrate 11 with an adhesive sheet. The end part of the substrate 10 is fixed to the case 3 of the light-emitting device 2 illustrated in FIG. 1A.

The metal substrate 11 functions as a mounting substrate for mounting the light-emitting units 20 and a heat radiation substrate for radiating heat generated in the light-emitting units 20, and thus, is made of, for example, aluminum that excels in heat resistance and heat radiation. However, the material of the metal substrate 11 may other metal, such as copper, as long as it excels in heat resistance and heat radiation.

The circuit substrate 12 is an insulating substrate, such as a glass epoxy substrate, a BT resin substrate, a ceramic substrate, or a metal core substrate. A conductive pattern 14 for electrically connecting the light-emitting units 20 to one another is formed on the upper surface of the circuit substrate 12. Two connection electrodes 15 for connecting the light-emitting device 2 to an external power source are formed on the right end of the circuit substrate 12 illustrated in FIG. 2A. One of the connection electrodes 15 is a positive electrode and the other of the connection electrodes 15 is a negative electrode, and a voltage is applied by connecting them to the external power source, so that the light-emitting units 20 of the light-emitting device 2 emit light.

The light-emitting units 20 are independent light-emitting units formed on the substrate 10 that is one common substrate, and are uniformly arranged on the substrate 10 so as to surround the opening 13. In the illustrated example, the light-emitting device 2 has twenty-two light-emitting units 20. As described below, each light-emitting unit 20 has LED elements (an example of light-emitting elements). Preferably, intervals (pitch) of the light-emitting units 20 are constant sizes so as to equalize emission light from the light-emitting device 2. However, the pitch of the light-emitting units 20 may differ between a vertical direction and a horizontal direction of the substrate 10.

FIG. 3 is a top view of the lens array 40. The lens array 40 is a lens assembly in which lenses 41 are integrally formed. In the illustrated example, the lens array 40 has twenty-two lenses 41 arranged closely except the center thereof. Preferably, a central part 42 of the lens array 40 is an opening. As illustrated in FIG. 2B, an optical axis X of each lens 41 corresponds to a normal line direction of the substrate 10. The lenses 41 are provided to respectively correspond to the light-emitting units 20 in the same arrangement as the light-emitting units 20 on the substrate 10, and collect beams of emission light from the corresponding light-emitting units 20, respectively. The respective lenses 41 have the same shape and size, for example.

The end part of the lens array 40 is fixed to the case 3 of the light-emitting device 2 illustrated in FIG. 1A. In particular, for use in a flood lamp, the light-emitting device 2 is desired to be downsized as much as possible so as to make resistance from wind during use lower. Therefore, preferably, the adjacent lenses 41 are in contact with one another without intervals, and the density of the lenses 41 to the whole of the lens array 40 is increased. Since the light-emitting units 20 and the lenses 41 are in one-to-one correspondence, the pitch of the light-emitting units 20 is determined by the diameter of the lens 41.

As described above, the substrate 10 has the opening 13 at the center. The opening 13 is formed at the same position of the metal substrate 11 and the circuit substrate 12. In addition, preferably, the lenses 41 are not arranged above the opening 13, and the lens array 40 is opened above the opening 13. The shape of the opening 13 may have another shape, such as a rectangular shape, without limiting to the circular shape, and the position of the opening 13 may not be the strict center of the substrate 10. Since the substrate 10 has the opening 13, the light-emitting device 2 has an advantage from the viewpoint of heat radiation, as described below.

First, in the light-emitting device 2, the metal substrate 11 is exposed at the edge of the opening 13, and thus, an area of contact between the outside air and the metal substrate 11 is increased. Accordingly, a part of heat transferred to the metal substrate 11 from the light-emitting units 20 (light-emitting elements) is released to the outside of the device also from the edge of the opening 13. In addition, in the light-emitting device 2, the heat radiation fin 4 on the rear side of the substrate 10 is in contact with the outside air also on the front side of the substrate 10 through the opening 13, and thus, an area of contact between the outside air and the heat radiation fin 4 is also increased. Accordingly, a part of heat transferred to the heat radiation fin 4 from the metal substrate 11 is also released to the front side of the substrate 10 through the opening 13. Therefore, in the light-emitting device 2, release of heat generated in the respective light-emitting units 20 (light-emitting elements) to the outside of the device can be promoted by the opening 13.

From the viewpoint of heat radiation, the diameter of the opening 13 needs to have a certain size. For example, a diameter d1 of the opening 13 is preferably at least larger than a diameter d2 of each light-emitting unit 20, and is more preferably larger than arrangement intervals (pitch) d3 of the light-emitting units 20. In the illustrated example, the pitch d3 of the light-emitting units 20 is larger than the diameter d2 of the light-emitting unit 20.

In addition, as illustrated in FIG. 2A, in each light-emitting unit 20, inspection terminals 16 for checking operation (lighting) of the light-emitting unit 20 are provided on the upper surface of the circuit substrate 12. The inspection terminals 16 form pairs (groups) of two terminals, and are arranged so as to sandwich the respective light-emitting units 20. The inspection terminals 16 are arranged at the outside of the light-emitting units 20; however, when the arrangement positions of the inspection terminals 16 are too far away from the respective light-emitting units 20, routing of the conductive pattern is difficult since there is also the conductive pattern 14 for lighting the light-emitting units 20 at one time on the circuit substrate 12. Thus, as illustrated in FIG. 2A, the inspection terminals 16 of each pair are formed at positions on the circuit substrate 12 in a diameter of a principal surface of the lens 41 corresponding to the targeted light-emitting unit 20.

In addition, in order to prevent erroneous measurement, the two inspection terminals 16 of each pair are uniformly arranged with an interval d therebetween, which is common among the light-emitting units 20. Furthermore, the two inspection terminals 16 of each pair are preferably arranged at a common angle with respect to a side of the substrate 10, if the conductive pattern 14 allows this arrangement. As just described, by aligning the arrangement of a plurality of pairs of the inspection terminals 16, when the operation of the light-emitting units 20 is checked sequentially, the operation check of each light-emitting unit 20 is easy, and the occurrence frequency of erroneous measurement can be lowered.

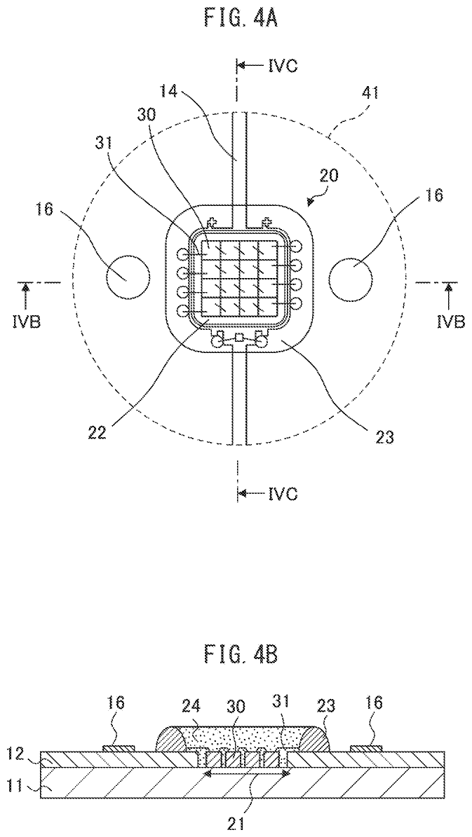

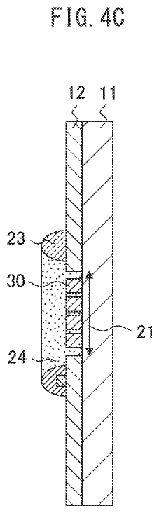

FIG. 4A is a top view of the light-emitting unit 20, FIG. 4B is a cross-sectional view of the light-emitting unit 20 along the line IVB-IVB of FIG. 4A, and FIG. 4C is a cross-sectional view of the light-emitting unit 20 along the line IVC-IVC of FIG. 4A. The light-emitting unit 20 has LED elements 30, a sealing frame 23, and a sealing resin 24 as main components.

The LED elements 30 are an example of light-emitting elements, and are, for example, blue LEDs that emit blue light having an emission wavelength band of about 450 to 460 nm. In each light-emitting unit 20, there is an opening 21 in the circuit substrate 12, and the metal substrate 11 is exposed through the opening 21. The LED elements 30 are mounted on the metal substrate 11 exposed through the opening 21. The LED elements 30 are directly mounted on the metal substrate 11 in this manner, so that release of heat generated by the LED elements 30 and phosphor particles described below is promoted.

In addition, the LED elements 30 are arranged in a lattice pattern and mounted in, for example, a rectangular mount region 22 in the opening 21. In FIG. 4A, in particular, an example of the case where four rows and four columns sixteen LED elements 30 are mounted is illustrated. The LED elements 30 are arranged in strings of four series-connected elements, and the four strings thereof are further connected in parallel. As just described, in each light-emitting unit 20, the LED elements 30 are series-parallel connected to one another so as to include a predetermined number of series connections (series-connected elements) and a predetermined number of parallel connections (parallel-connected strings) which are set for the light-emitting unit 20.

Hereinafter, in particular, a light-emitting unit in which the number of series connections of the LED elements 30 is four is referred to as “light-emitting unit 20₄”. A light-emitting unit that is not distinguished by the number of series connections of the LED elements 30 is simply referred to as “light-emitting unit 20”.

The lower surfaces of the LED elements 30 are fixed to the upper surface of the metal substrate 11 with a transparent and insulating adhesive agent, for example. In addition, each LED element 30 has a pair of element electrodes on the upper surface thereof, and as illustrated in FIG. 4A, the element electrodes of the adjacent LED elements 30 are mutually and electrically connected by wires 31. The wires 31 from the LED elements 30 positioned on the outer peripheral side of the opening 21 are electrically connected to the conductive pattern 14 of the circuit substrate 12. Accordingly, a current is supplied to the respective LED elements 30 through the wires 31.

The sealing frame 23 is a substantially rectangular resin frame made of a white resin, for example, according to the size of the opening 21 of the circuit substrate 12, and is fixed to the outer peripheral part of the opening 21 on the upper surface of the circuit substrate 12 so as to surround the LED elements 30 in the light-emitting unit 20. The sealing frame 23 is a dam material for preventing flow of the sealing resin 24. In addition, for example, reflective coating is applied to the surface of the sealing frame 23, and thereby the sealing frame 23 reflects light emitted laterally from the LED elements 30 toward the upper side of the light-emitting unit 20 (the opposite side of the metal substrate 11 as viewed from the LED elements 30). In FIG. 4A, the sealing frame 23 is illustrated as being transparent.

The sealing resin 24 is filled in a region surrounded by the sealing frame 23 on the metal substrate 11, and thereby integrally covers and protects (seals) the whole of the LED elements 30 and the wires 31 of the light-emitting unit 20. As the sealing resin 24, for example, a colorless and transparent resin, such as an epoxy resin or a silicone resin, and, in particular, a resin having a heat resistance of about 250° C. may be used.

In addition, a phosphor, such as a yellow phosphor, is dispersedly mixed in the sealing resin 24. The yellow phosphor is a particulate phosphor material, such as yttrium aluminum garnet (YAG), which absorbs blue light emitted by the LED elements 30 and performs wavelength conversion into yellow light. The light-emitting unit 20 emits white light obtained by mixing blue light from the LED elements 30 that are blue LEDs, and yellow light obtained by exciting the yellow phosphor thereby.

Alternatively, the sealing resin 24 may contain a plurality of different phosphors, such as a green phosphor and a red phosphor. The green phosphor is a particulate phosphor material, such as (BaSr)₂SiO₄:Eu²⁺, which absorbs blue light emitted by the LED elements 30 and performs wavelength conversion into green light. The red phosphor is a particulate phosphor material, such as CaAlSiN₃:Eu²⁺, which absorbs blue light emitted by the LED elements 30 and performs wavelength conversion into red light. In this case, the light-emitting unit 20 emits white light obtained by mixing blue light from the LED elements 30 that are blue LEDs, and green light and red light obtained by exciting the green phosphor and the red phosphor thereby.

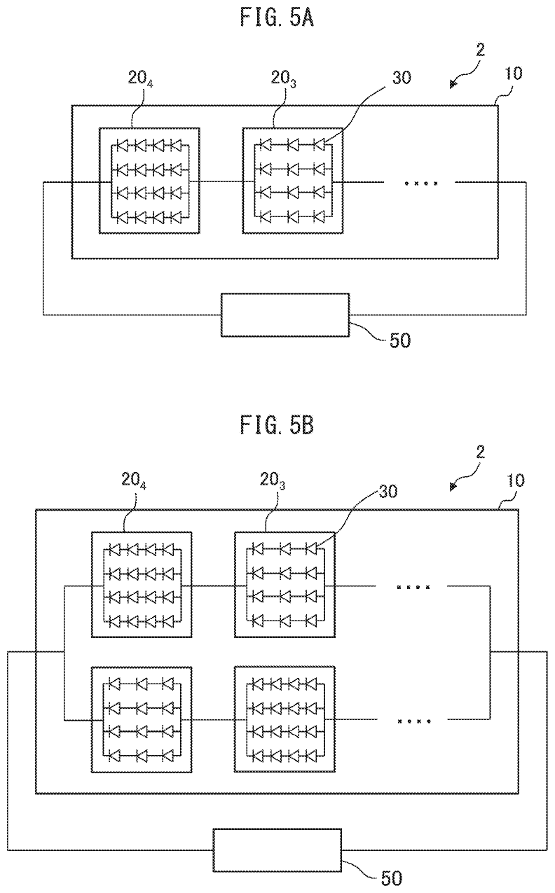

FIG. 5A and FIG. 5B are circuit diagrams of the whole of the light-emitting device 2. The reference numeral 50 denotes a driver that drives the twenty-two light-emitting units 20 of the light-emitting device 2, and the reference numeral 20₃ denotes a light-emitting unit in which the number of series connections of the LED elements 30 is three. In the substrate 10, as illustrated in FIG. 2A, a total of five switching terminals 17 are provided on the upper surface of the circuit substrate 12. In the light-emitting device 2, the series-parallel of the light-emitting units 20 can be switched by changing a way of connecting the switching terminals 17 depending on a relationship between the number of the light-emitting devices 2 included in the lighting apparatus 1 and the maximum voltage that the driver 50 used can supply. For example, depending on the way of connecting the switching terminals 17, the twenty-two light-emitting units 20 are connected in series with the driver 50 as illustrated in FIG. 5A, and the twenty-two light-emitting units 20 are divided into two groups that are connected in parallel with one another to the driver 50 and eleven light-emitting units 20 included in each group are connected in series with one another as illustrated in FIG. 5B.

As described above, each light-emitting unit 20 has the LED elements 30 that are divided into a plurality of columns connected in parallel with one another and are connected in series with one another in each of the columns. In the light-emitting device 2, the number of the LED elements 30 connected in series in each light-emitting unit 20 is set such that the sum of forward voltages (Vf) of the LED elements 30 connected in series in the whole of the device falls within a range of a voltage that the driver 50 can drive. Therefore, in the light-emitting device 2, all of the light-emitting units 20 do not necessarily have the same number of the LED elements 30, and generally, the number of the LED elements 30 included in one light-emitting unit 20 is different in each light-emitting unit 20.

For example, it is assumed that the maximum voltage that the driver 50 can supply is 264 V. In addition, it is assumed that, when certain LED elements (1) are used as the LED elements 30, Vf of one light-emitting unit 20 in which the number of series connections is four is 10.5 to 11.7 V. In this case, when the twenty-two light-emitting units 20 are connected in series, Vf of the whole of the light-emitting device 2 is 231.0 to 257.4 V, and falls within the range that the driver 50 can drive. On the other hand, it is assumed that, when other LED elements (2) are used as the LED elements 30, Vf of one light-emitting unit 20 in which the number of series connections is four is 11.6 to 13.6 V. In this case, when the twenty-two light-emitting units 20 are connected in series, Vf of the whole of the light-emitting device 2 is 255.0 to 299.4 V, and exceeds the maximum voltage that the driver 50 can drive.

Therefore, when the latter LED elements (2) are used, the number of series connections is made to be three in some of the light-emitting units 20, and light-emitting units 20₄ in each of which the number of series connections is four and Vf is 11.6 to 13.6 V and light-emitting units 20₃ in each of which the number of series connections is three and Vf is 8.69 to 10.21 V are combined. Then, when at least eleven light-emitting units 20 among the twenty-two light-emitting units 20 in total are made to be the light-emitting units 20₃, Vf of the whole of the light-emitting device 2 is less than 264 V, and falls within the range that the driver 50 can drive. Thus, in the light-emitting device 2, when the LED elements (1) are used, the twenty-two light-emitting units 20 are made to be the light-emitting units 20₄ in each of which the number of series connections is four, but when the LED elements (2) are used, for example, eleven light-emitting units 20 among the twenty-two light-emitting units 20 are made to be the light-emitting units 20₄ in each of which the number of series connections is four, and the remaining eleven light-emitting units 20 are made to be the light-emitting units 20₃ in each of which the number of series connections is three.

As just described, in the light-emitting device 2, the number of the LED elements 30 connected in series in each light-emitting unit 20 is different, for example, m in a certain light-emitting unit 20 and n in another light-emitting unit 20. Accordingly, the sum of the forward voltages of the LED elements 30 connected in series in the whole of the device is adjusted to fall within the range of the voltage that the targeted driver 50 can drive. Therefore, even when the type of the LED elements 30 used is changed, the light-emitting device 2 can be driven by the common driver 50 regardless of the forward voltage of each LED element 30.

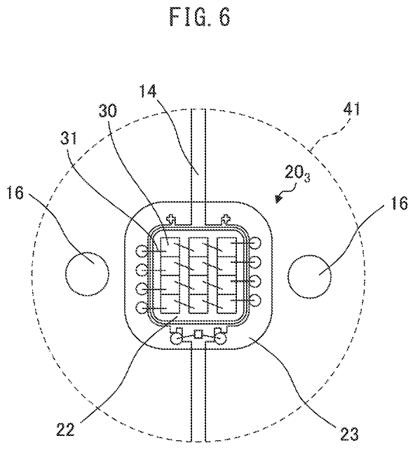

FIG. 6 is a top view of the light-emitting unit 20₃. The light-emitting unit 20 illustrated in FIG. 4A (the light-emitting unit 20₄) and the light-emitting unit 20₃ illustrated in FIG. 6 are different only in the number of the LED elements 30, and have the same configurations in other respects. The light-emitting unit 20₄ has sixteen LED elements 30, which are arranged in strings of four series-connected elements, and the four strings thereof are further connected in parallel, whereas the light-emitting unit 20₃ has twelve LED elements 30, which are arranged in strings of three series-connected elements, and the four strings thereof are further connected in parallel.

In both the light-emitting units 20₄ and 20₃, the mount region 22 is a rectangular region having the same shape and size, and the LED elements 30 are certainly mounted on at least four corners of the mount region 22. Furthermore, in both the light-emitting units 20₄ and 20₃, the LED elements 30 are, for example, uniformly mounted at the inner side of the mount region 22. The light-emitting units 20₄ and 20₃ both have the same size of the mount region 22 but are different in the pitch of the elements, so that the mounting density of the LED elements 30 is different from each other. In addition, the light-emitting density when the light-emitting unit is viewed as one luminous body is also different between the light-emitting units 20₄ and 20₃.

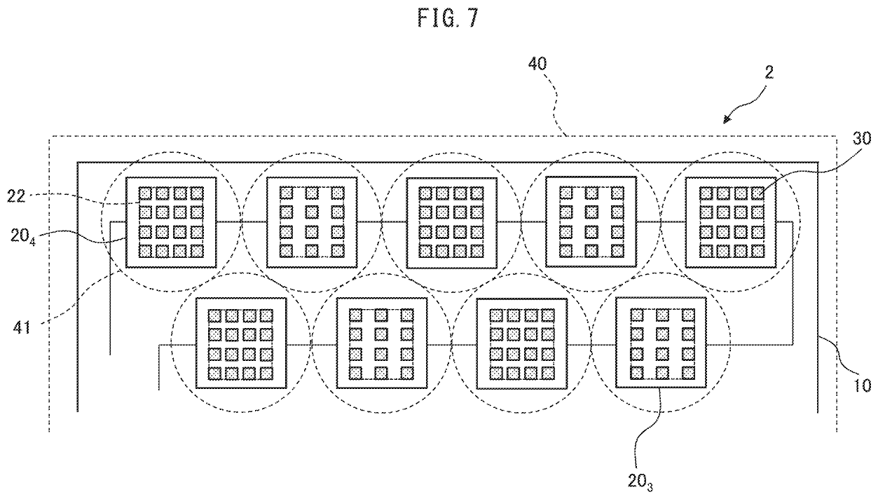

FIG. 7 is a diagram schematically illustrating the arrangement of the LED elements 30 in the light-emitting device 2. Although the light-emitting units are simply referred to as “light-emitting units 20” without distinction in FIG. 2A and FIG. 2B, in the light-emitting device 2, as described above, for example, the light-emitting units 20₄ in each of which the number of series connections is four and the light-emitting units 20₃ in each of which the number of series connections is three are combined so as to adjust the forward voltage of the whole of the device. FIG. 7 illustrates an example of the case where the light-emitting units 20₄ and the light-emitting units 20₃ are alternately connected. However, the number of series connections of the LED elements 30 may be the same in all of the light-emitting units 20, or there may be a light-emitting unit 20 in which the number of series connections is two or less or five or more, depending on the driver 50 used.

As just described, the LED elements 30 of each light-emitting unit 20 are mounted in the mount region 22 whose shape and size are common in the light-emitting units 20, at the mounting density according to the number of series connections and the number of parallel connections which are set for the light-emitting unit 20. Accordingly, the light-emitting diameters are the same among the light-emitting units 20, and thus, the lens array 40 including the lenses 41 having the same shape and size can be used regardless of the number of the LED elements 30 included in each light-emitting unit 20.

Since the emission light quantity is decreased in a light-emitting unit 20 in which the number of the LED elements 30 is relatively decreased, when light-emitting units 20 in which the number of series connections and/or the number of parallel connections is different from one another are combined, unevenness of the emission light quantity can be generated as the whole of the light-emitting device 2. Thus, for a light-emitting unit 20 in which the number of series connections and the number of parallel connections of the LED elements 30 are smaller, LED elements having higher forward voltages may be used as the LED elements 30. Since the LED elements having higher forward voltages make the emission light brighter, by selecting the LED elements used in each light-emitting unit 20, the emission light quantity can be equalized among the light-emitting units 20, and thereby light without unevenness can be emitted.

However, since the lighting apparatus 1 is located at a position distant from human eyes because of being used as a flood lamp, unevenness of brightness on the light-emitting device 2 does not matter too much. Therefore, light-emitting units 20 in which the number of series connections and/or the number of parallel connections is different from one another are not necessarily uniformly arranged in the light-emitting device 2. In addition, LED elements having the same forward voltage may be used in all of the light-emitting units 20.

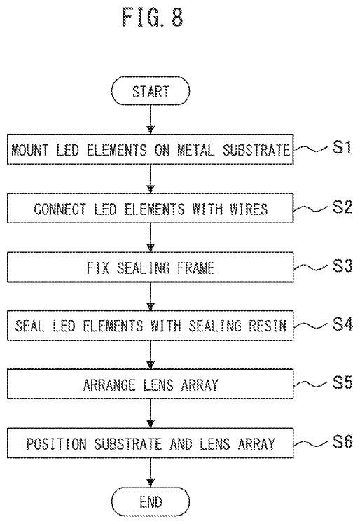

FIG. 8 is a flowchart illustrating an example of a manufacturing process of the light-emitting device 2. At the time of manufacture of the light-emitting device 2, first, the light-emitting units 20 are formed at one time on the substrate 10, and a plurality of groups of the LED elements 30 are mounted on the respective light-emitting units 20. On this occasion, for each light-emitting unit 20, the LED elements 30 are mounted on the metal substrate 11 in the opening 21 of the circuit substrate 12 (S1). Next, the LED elements 30 are series-parallel connected to one another with the wires 31 (S2). In addition, the sealing frame 23 is fixed to the outer peripheral part of the opening 21 (S3). Furthermore, the sealing resin 24 containing a phosphor is filled in a region surrounded by the sealing frame 23 on the metal substrate 11, so that the LED elements 30 are sealed (S4).

As illustrated in FIG. 2A, two positioning holes 18a, 18b, as an example, are formed on a diagonal line of the upper surface of the circuit substrate 12. The position of the opening 21 of the circuit substrate 12 corresponding to each light-emitting unit 20 is determined based on the positions of the positioning holes 18a, 18b. In other words, the mounting positions of the LED elements 30 and the arranging position of the sealing frame 23 of each light-emitting unit 20 are determined based on the positions of the positioning holes 18a, 18b. Accordingly, variations in forming positions of the light-emitting units 20 are decreased.

Subsequently, the lens array 40 including the lenses 41 is arranged on the light-emitting units 20 with the positions of the respective light-emitting units 20 relatively and roughly conforming to the positions of the corresponding lenses 41 (S5). On this occasion, for example, by holding the end parts of the substrate 10 and the lens array 40 with the case 3, the lens array 40 is fixed with respect to the substrate 10. Alternatively, the lens array 40 may be fixed with respect to the substrate 10 by a method described below.

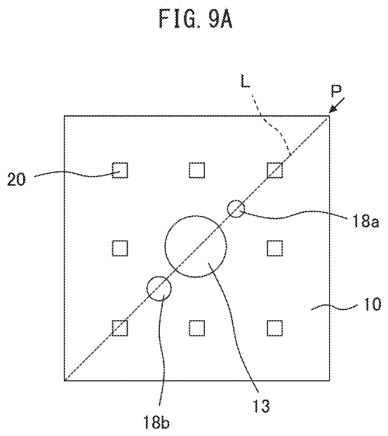

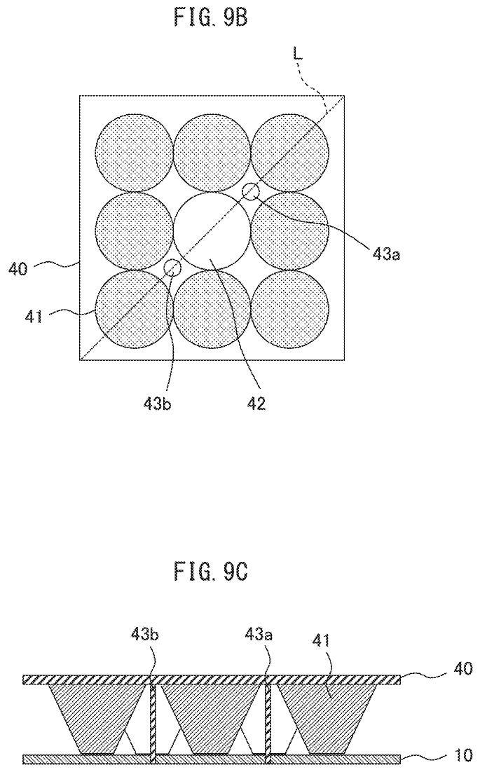

FIG. 9A to FIG. 9C are diagrams illustrating an example of a method for fixing the lens array 40 with respect to the substrate 10. FIG. 9A to FIG. 9C illustrate a top view of the substrate 10, a top view of the lens array 40, and a vertical cross-sectional view of the light-emitting device 2 along the diagonal line L, respectively. FIG. 9A to FIG. 9C illustrate the light-emitting units 20 and the lenses 41 as the number thereof being eight, for simplification.

In the illustrated example, the substrate 10 and the lens array 40 are positioned using the positioning holes 18a, 18b. In this case, on the diagonal line L of the lower surface of the lens array 40 (a surface opposed to the substrate 10), two support units 43a, 43b are provided in advance according to the positions of the positioning holes 18a, 18b. The support units 43a, 43b are columnar members that are integrally formed with the lens array 40 or bonded to the lens array 40. The support units 43a, 43b are fitted into the positioning holes 18a, 18b, respectively, so that the substrate 10 and the lens array 40 are positioned. Accordingly, the optical axis of each lens 41 can be easily aligned with the center of each light-emitting unit 20, and thus, the step of adjusting the relative position between the light-emitting units 20 and the lenses 41 is simplified.

Diameters along the diagonal line L of the positioning holes 18a, 18b become larger with increasing a distance from one end part P of the diagonal line L. For example, as illustrated in FIG. 2A and FIG. 9A, both the positioning holes 18a, 18b have a circular shape, and the positioning hole 18b farther away from the one end part P than the positioning hole 18a has a larger diameter. Alternatively, the positioning holes 18a, 18b may have an oval shape (elongate holes) with the direction of the diagonal line L as the long axis, and in this case, the positioning hole 18b has a larger major axis than the positioning hole 18a. In addition, diameters of parts at the lower ends of the support units 43a, 43b, which are fitted into the positioning holes 18a, 18b, are slightly thinner than the positioning holes 18a, 18b. Accordingly, the relative position between the light-emitting units 20 and the lenses 41 along the diagonal line L can be changed, and thus, even when the substrate 10 and the lens array 40 thermally expand or thermally contract at different rates, fine adjustment of the relative position is possible.

Thus, the substrate 10 and the lens array 40 are fixed with each other such that the relative position between the light-emitting units 20 and the lenses 41 can be changed in accordance with thermal expansion during lighting of the light-emitting device 2 and thermal contraction during lighting-off of the light-emitting device 2. Furthermore, accurate positioning between the substrate 10 and the lens array 40 is performed by a method described below (S6).

The positioning between the substrate 10 and the lens array 40 in S6 is performed in accordance with the following idea. The metal substrate 11 made of aluminum and the circuit substrate 12 made of a resin, which configure the substrate 10, and the lens array 40 made of glass expand by heat generated during lighting of the light-emitting device 2 at different thermal expansion rates. For example, when it is assumed that temperatures of the substrate 10 and the lens array 40 are increased by about 100° C. by lighting, in the case where each side of the substrate 10 is about 10 cm, a difference in the amount of extension of about 1 mm can be generated between the substrate 10 and the lens array 40. Thus, in consideration of the difference Δd in the amount of extension, the relative position between the light-emitting units 20 and the lenses 41 is shifted by Δd in advance in opposite directions.

Accordingly, when the thermal expansion occurs by driving the light-emitting device 2 (lighting the light-emitting units 20), the preset amount of shift and the difference in the amount of extension due to the thermal expansion are canceled out each other, and each light-emitting unit 20 and the optical axis of each lens 41 correspond to each other. Therefore, when the thermal expansion occurs in the substrate 10 and the lens array 40 by driving the light-emitting device 2, the emission efficiency from each light-emitting unit 20 through each lens 41 can be improved.

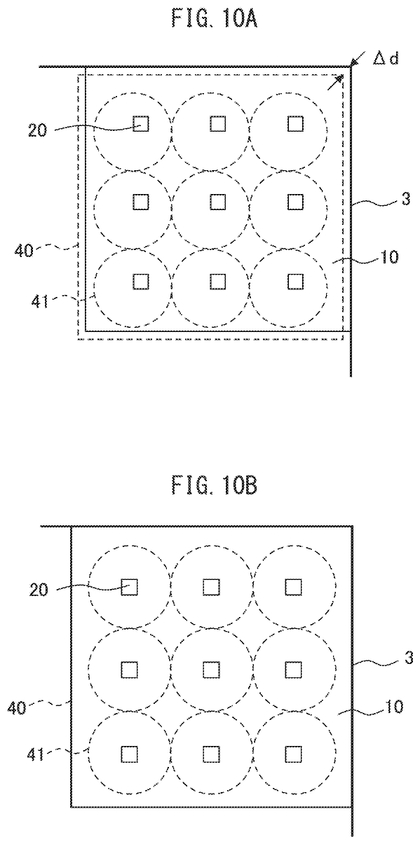

FIG. 10A and FIG. 10B are diagrams illustrating an example of a method for positioning the substrate 10 and the lens array 40. When the substrate 10 and the lens array 40 are positioned, for example, as illustrated in FIG. 10A, adjacent two sides of the substrate 10 and the end part of the lens array 40 corresponding to the two sides, as reference planes, are brought into contact with a wall of the case 3. Then, the lens array 40 having a smaller thermal expansion rate is shifted away from the reference planes by a length corresponding to the difference Δd in the amount of extension due to the thermal expansion of the substrate 10 and the lens array 40. The substrate 10 and the lens array 40 expand uniformly by the thermal expansion, and the whole is enlarged. Therefore, by the above-described step, when the substrate 10 and the lens array 40 thermally expand by lighting the light-emitting units 20, the positions of the respective light-emitting units 20 can relatively conform to the positions of the respective lenses 41, as illustrated in FIG. 10B.

Then, the manufacturing process of the light-emitting device 2 is finished. Modified examples of the light-emitting unit 20 will be described below.

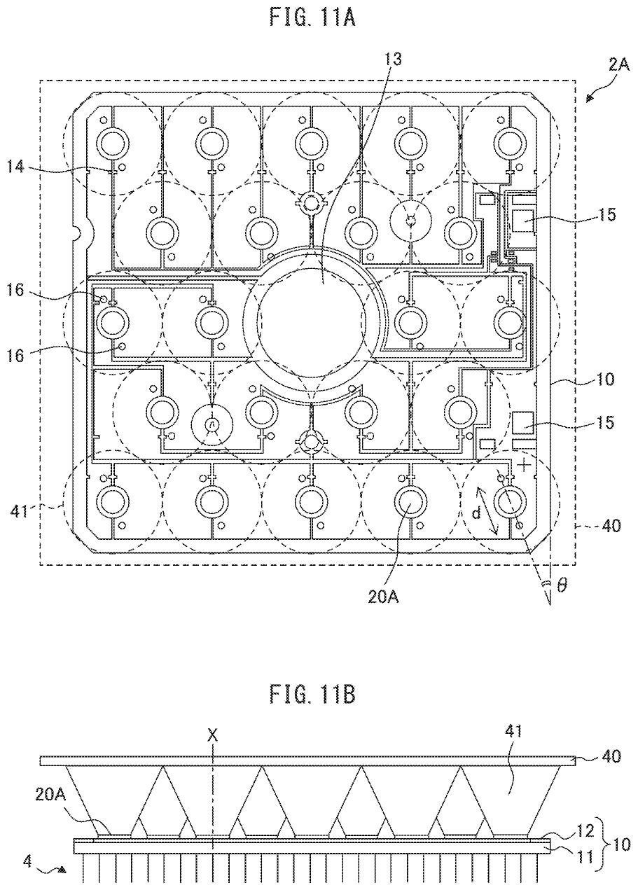

FIG. 11A and FIG. 11B are a top view and a side view of a light-emitting device 2A. The light-emitting device 2 illustrated in FIG. 2A and FIG. 2B and the light-emitting device 2A illustrated in FIG. 11A and FIG. 11B are different in the shape of the light-emitting units and the arrangement of the inspection terminals 16, and have the same configurations in other respects. The light-emitting units 20 of the light-emitting device 2 have a substantially rectangular shape, whereas light-emitting units 20A of the light-emitting device 2A are slightly larger than the light-emitting units 20 and have a circular shape. As just described, the shape of each light-emitting unit in the light-emitting device may be a circular shape or another shape without limiting to a rectangular shape. In addition, the inspection terminals 16 of the light-emitting device 2A are different from those of the light-emitting device 2 in the interval of the two terminals of each light-emitting unit 20A and the angle thereof with respect to a side of the substrate 10, but have the same configurations as those of the light-emitting device 2 in other respects. The inspection terminals 16 are arranged on the substrate 10 at an interval d and an angle θ in accordance with the shape of the light-emitting units.

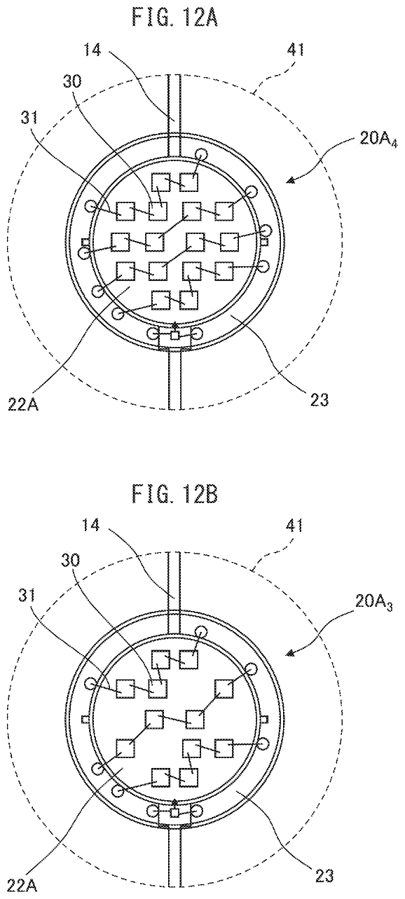

FIG. 12A and FIG. 12B are top views of the light-emitting unit 20A. FIG. 12A illustrates a light-emitting unit 20A₄ in which the number of series connections of the LED elements 30 is four and the number of parallel connections of the LED elements 30 is four. In addition, FIG. 12B illustrates a light-emitting unit 20A₃ in which the number of series connections of the LED elements 30 is four and the number of parallel connections of the LED elements 30 is three. As just described, also in the light-emitting device 2A, the LED elements 30 of each light-emitting unit 20A are mounted in a circular mount region 22A whose size is common in the light-emitting units 20A, at the mounting density according to the number of series connections and the number of parallel connections which are set for the light-emitting unit 20A. In this case, the number of series connections of the LED elements 30, the number of parallel connections of the LED elements 30, or both thereof may be different in each light-emitting unit 20A.

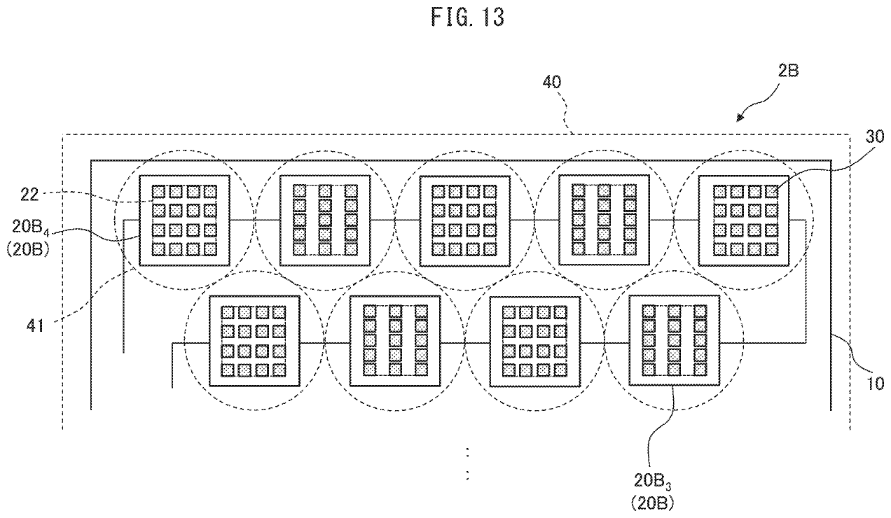

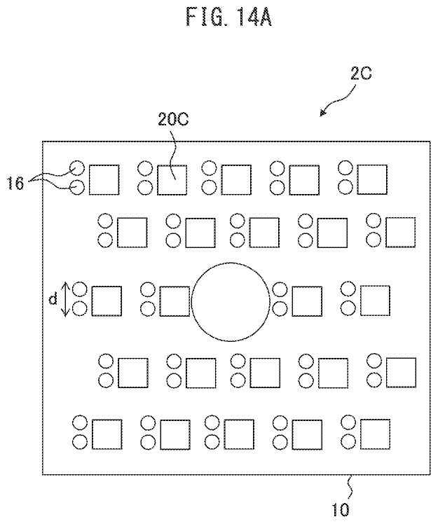

FIG. 13 is a diagram schematically illustrating the arrangement of the LED elements 30 in a light-emitting device 2B. The light-emitting device 2 illustrated in FIG. 7 and the light-emitting device 2B illustrated in FIG. 13 are different only in the number of series connections and the number of parallel connections of the LED elements 30 in each light-emitting unit, and have the same configurations in other respects. Although all of the light-emitting units 20 have the same number of parallel connections, four, in the light-emitting device 2, both the number of series connections and the number of parallel connections may be different in each light-emitting unit. The light-emitting device 2B illustrated in FIG. 13 has light-emitting units 20B₄ in each of which the number of series connections is four and the number of parallel connections is also four, and light-emitting units 20B₃ in each of which the number of series connections is three and the number of parallel connections is five. FIG. 13 illustrates an example of the case where the light-emitting units 20B₄ and the light-emitting units 20B₃ are alternately connected. Also when both the number of series connections and the number of parallel connections are varied in each light-emitting unit, preferably, the LED elements 30 of each light-emitting unit 20B are mounted in the mount region 22 whose shape and size are common in the light-emitting units 20B.

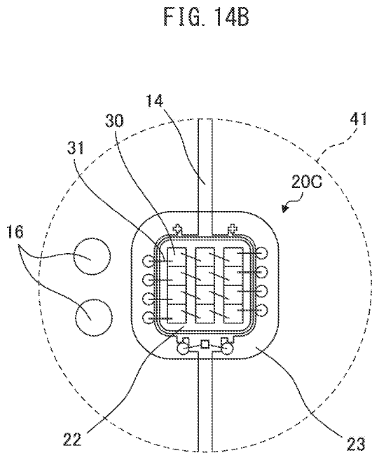

FIG. 14A and FIG. 14B are top views of a light-emitting device 2C and a light-emitting unit 20C in the light-emitting device 2C. The light-emitting device 2 illustrated in FIG. 2A and the light-emitting device 2C illustrated in FIG. 14A are different only in the arrangement of the inspection terminals 16 of each light-emitting unit, and have the same configurations in other respects. Although the inspection terminals 16 of each pair are arranged so as to sandwich the light-emitting unit 20 in the light-emitting device 2, the inspection terminals 16 of each pair may be arranged at one side of the light-emitting unit 20C without sandwiching the light-emitting unit 20C, as illustrated in FIG. 14A and FIG. 14B. Also in this case, the two inspection terminals 16 of each pair are uniformly arranged with an interval d therebetween, which is common among the light-emitting units 20C.

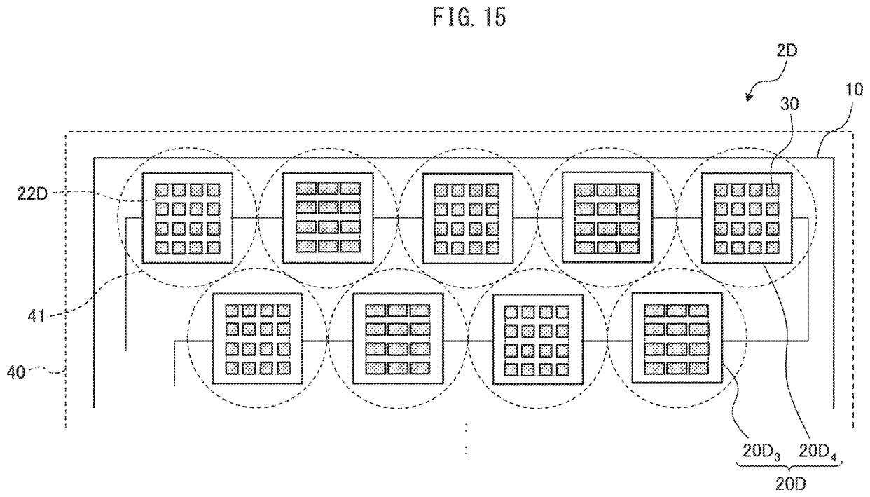

FIG. 15 is a diagram schematically illustrating the arrangement of the LED elements 30 in a light-emitting device 2D. Although the size of the LED elements 30 is different in each light-emitting unit 20D, the light-emitting device 2D illustrated in FIG. 15 has the same configurations as those of the light-emitting device 2 illustrated in FIG. 7 in other respects. In the light-emitting device 2D, areas of light-emitting regions 22D of light-emitting units 20D are equal to one another, and the size of the LED elements 30 included in each light-emitting unit 20D is smaller in a light-emitting unit 20D in which the number of series connections of the LED elements 30 is larger.

Accordingly, even when the number of the elements is changed in each light-emitting unit 20D, the lens array including the lenses having the same outer shape can be used. In addition, by decreasing the size of the elements, the number of series connections in the light-emitting region 22D having the same area can be increased, and the forward voltage of each light-emitting unit 20D can be adjusted in accordance with the number of series connections, and thus, the forward voltage of the whole of the device can be made to fall within a range that a driver for the light-emitting device 2D can drive. In the light-emitting devices 2A to 2C that have been described above, as just described, the LED elements 30 having a different size may be used for a light-emitting unit in which the number of series connections is different.

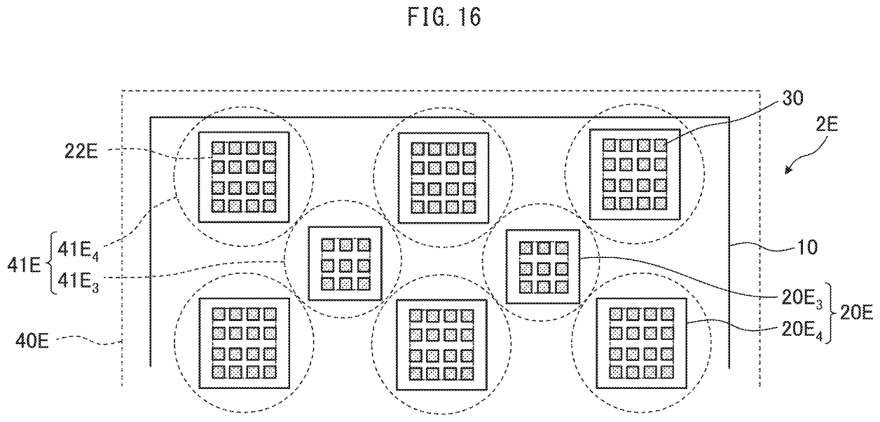

FIG. 16 is a diagram schematically illustrating the arrangement of the LED elements 30 in a light-emitting device 2E. Although the size of each lens 41E in a lens array 40E is different in each light-emitting unit 20E, the light-emitting device 2E illustrated in FIG. 16 has the same configurations as those of the light-emitting device 2 illustrated in FIG. 7 in other respects. The size of each lens 41E is larger as the number of the LED elements 30 included in the light-emitting unit 20E corresponding to the lens 41E is larger.

For example, the light-emitting units 20E of the light-emitting device 2E are configured by light-emitting units 20E₄ (an example of first light-emitting units) having sixteen LED elements 30 that are series-parallel connected to one another so as to include series connections of four elements (the number of series connections is four) and parallel connections of four strings (the number of parallel connections is four), and light-emitting units 20E₃ (an example of second light-emitting units) having nine LED elements 30 that are series-parallel connected to one another so as to include series connections of three elements (the number of series connections is three) and parallel connections of three strings (the number of parallel connections is three). In the light-emitting device 2E, the mounting density of the LED elements 30 is the same in each light-emitting unit 20E, so that the size of a light-emitting region 22E is different in each light-emitting unit 20E. In addition, lenses 41E of the light-emitting device 2E are configured by lenses 41E₄ that correspond to the light-emitting units 20E₄, and lenses 41E₃ that correspond to the light-emitting units 20E₃ and are smaller than the lenses 41E₄. FIG. 16 illustrates an example of the case where the light-emitting units 20E₄ and the light-emitting units 20E₃ are alternately arranged on the substrate 10.

As just described, by changing the size of the lenses 41E in accordance with the number of the LED elements 30 in each light-emitting unit 20E, i.e., the size of the light-emitting region 22E, the small light-emitting units 20E₃ can be arranged between the large light-emitting units 20E₄. Therefore, in the light-emitting device 2E, many light-emitting units 20E can be formed on the surface of the substrate 10 at a higher density, and the emission light quantity is increased.

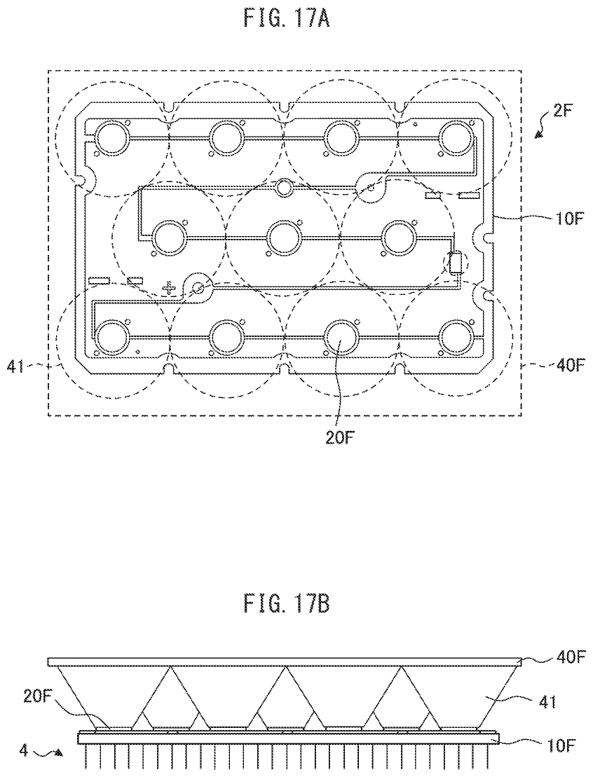

FIG. 17A and FIG. 17B are a top view and a side view of a light-emitting device 2F. In the light-emitting device 2F illustrated in FIG. 17A, an opening is not provided at the center of a substrate 10F unlike the light-emitting device 2A illustrated in FIG. 11A. In addition, the substrate 10F and a lens array 40F of the light-emitting device 2F are smaller than the substrate 10 of the light-emitting device 2A, and the number of light-emitting units 20F of the light-emitting device 2F is smaller than the number of the light-emitting units 20A of the light-emitting device 2A. The light-emitting device 2F has the same configurations as those of the light-emitting device 2A in other respects. The light-emitting units 20F may have the same configurations as those of the light-emitting units 20, and 20B to 20E that have been described above, and even in this case, an opening may not be provided at the center of the substrate 10F.

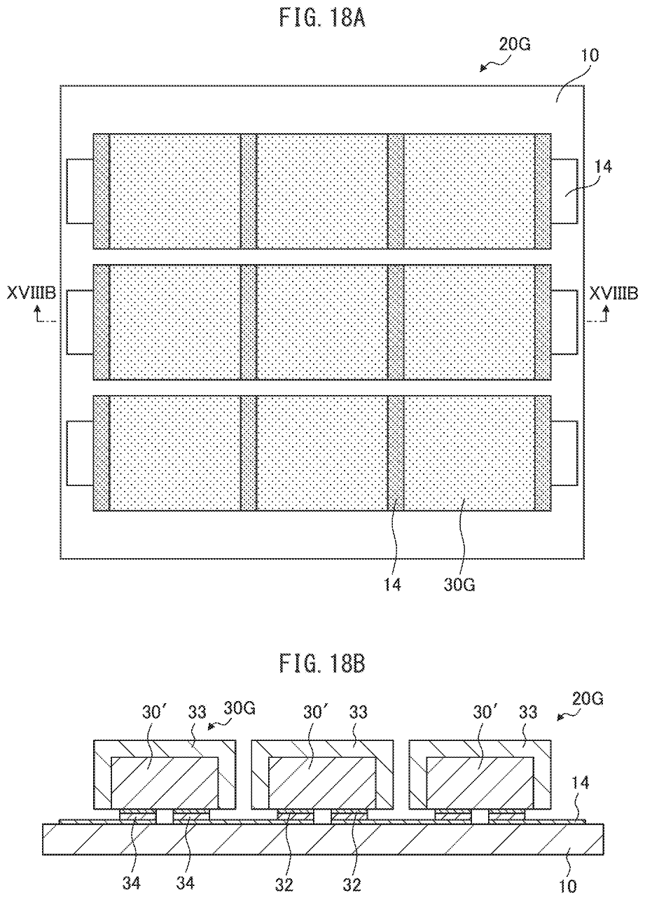

FIG. 18A is a top view of a light-emitting unit 20G, and FIG. 18B is a cross-sectional view of the light-emitting unit 20G along the line XVIIIB-XVIIIB of FIG. 18A. In FIG. 18A, an example of the case where nine LED packages 30G are mounted in a 3×3 lattice pattern is illustrated. The above-described light-emitting units 20, and 20A to 20F of the light-emitting devices 2, and 2A to 2F may be those configured by flip-chip mounting the LED packages 30G as illustrated in FIG. 18A and FIG. 18B, without limiting to those in which the LED elements 30 are connected by the wires 31 and the whole is sealed with the sealing resin 24.

Each LED package 30G has an LED element 30′ on whose lower surface two element electrodes 32 are formed, and a phosphor layer 33. The LED package 30G is a bump-type light-emitting element in which bumps 34 for flip-chip bonding are formed on the element electrodes 32 on the lower surface of the LED element 30. The LED element 30′ is, for example, a blue semiconductor light-emitting element (blue LED) that emits blue light having an emission wavelength band of about 450 to 460 nm.

The phosphor layer 33 is configured by dispersedly mixing phosphor particles in a colorless and transparent resin, such as an epoxy resin or a silicone resin, for example, and uniformly covers the upper surface and the side surfaces of the LED element 30′. For example, the phosphor layer 33 contains a yellow phosphor, such as YAG, and absorbs blue light emitted by the LED element 30′ and performs wavelength conversion into yellow light. In this case, the LED package 30G emits white light obtained by mixing blue light from the LED element 30′ that is a blue LED, and yellow light obtained by exciting the yellow phosphor thereby. The phosphor that the phosphor layer 33 contains may be another type of phosphor, and may be different in each LED package 30G.

1. A light-emitting device comprising:
a substrate;
light-emitting units arranged on the substrate; and
a lens array including lenses provided corresponding to the light-emitting units, respectively, to collect beams of emission light from the respective light-emitting units, the lens array being arranged on the light-emitting units, wherein
each of the light-emitting units has light-emitting elements that are mounted on the substrate in a lattice pattern and are series-parallel connected to one another in a mount region whose shape is common in the light-emitting units so as to include a predetermined number of series connections and a predetermined number of parallel connections which are set for the light-emitting unit.

2. The light-emitting device according to claim 1, wherein in each of the light-emitting units, the light-emitting elements are mounted in a mount region whose shape and size are common in the light-emitting units at a mounting density different in each light-emitting unit.

3. The light-emitting device according to claim 2, wherein in the light-emitting units, a light-emitting unit in which the number of series connections is smaller has LED elements having higher forward voltages as the light-emitting elements.

4. The light-emitting device according to claim 2, wherein
the mount region has a rectangular shape, and,
in each of the light-emitting units, the light-emitting elements are mounted on at least four corners of the rectangular shape.

5. The light-emitting device according to claim 2, wherein each of the light-emitting units
has LED elements mounted on the substrate and electrically connected to one another by wires, as the light-emitting elements, and
further has a sealing resin that contains a phosphor and is filled on the substrate to seal the LED elements.

6. The light-emitting device according to claim 2, wherein
each of the light-emitting units has LED packages flip-chip mounted on the substrate, as the light-emitting elements, and
each of the LED packages has an LED element and a resin layer that contains a phosphor and covers an upper surface and side surfaces of the LED element.

7. The light-emitting device according to claim 1, further comprising a driver that drives the light-emitting units, wherein
the light-emitting elements are LED elements, and
the number of LED elements connected in series in each of the light-emitting units is set such that a sum of forward voltages of LED elements connected in series in the whole of the light-emitting units falls within a range of a voltage that the driver can drive.

8. The light-emitting device according to claim 7, wherein the light-emitting units are connected in series with the driver.

9. The light-emitting device according to claim 7, wherein
the light-emitting units are divided into a plurality of groups that are connected in parallel with the driver, and
light-emitting units included in each of the groups are connected in series with one another.

10. The light-emitting device according to claim 1, wherein
the substrate is a metal substrate having an opening,
the light-emitting units are uniformly arranged on the metal substrate so as to surround the opening, and
each of the light-emitting units further has
a sealing frame that surrounds the light-emitting elements, and
a sealing resin that is filled in a region surrounded by the sealing frame on the metal substrate to seal the light-emitting elements.

11. The light-emitting device according to claim 10, further comprising a heatsink that is attached to a rear surface of the metal substrate and radiates heat generated by the light-emitting units.

12. The light-emitting device according to claim 10, wherein a diameter of the opening is larger than arrangement intervals of the light-emitting units.

13. The light-emitting device according to claim 10, wherein the lenses are not arranged above the opening.

14. The light-emitting device according to claim 1, further comprising a plurality of groups of inspection terminals, each of which is formed corresponding to each of the light-emitting units at positions on the substrate in a diameter of a principal surface of one of the lenses corresponding to the light-emitting unit, the positions being separated with an interval common in the light-emitting units.

15. The light-emitting device according to claim 14, wherein the plurality of groups of inspection terminals are pairs of two terminals, and are arranged at a common angle with respect to a side of the substrate.

16. The light-emitting device according to claim 1, wherein
each of the light-emitting units has LED elements mounted at the same mounting density as those in the light-emitting units, as the light-emitting elements, and
each of the lenses has a larger size as the number of the LED elements included in a light-emitting unit corresponding to the lens is larger.

17. The light-emitting device according to claim 16, wherein
the light-emitting units are configured by first light-emitting units each having LED elements that are series-parallel connected to one another so as to include a first number of series connections and a first number of parallel connections, and second light-emitting units each having LED elements that are series-parallel connected to one another so as to include a second number of series connections smaller than the first number of series connections and a second number of parallel connections smaller than the first number of parallel connections, and
the first light-emitting units and the second light-emitting units are alternately arranged on the substrate.

18. The light-emitting device according to claim 1, wherein the light-emitting elements have a smaller size in a light-emitting unit in which the number of light-emitting elements connected in series is larger.

19. The light-emitting device according to claim 18, wherein areas of light-emitting regions of the light-emitting units are equal to one another.

20. A manufacturing method of a light-emitting device, comprising the steps of:
forming light-emitting units by mounting a plurality of groups of light-emitting elements on a substrate; and
arranging a lens array including lenses arranged according to arrangement positions of the light-emitting units, on the light-emitting units, wherein,
in the forming step, in each of the light-emitting units, light-emitting elements whose number is set for the light-emitting unit are mounted in a lattice pattern in a mount region whose shape is common in the light-emitting units, and the light-emitting elements are series-parallel connected to one another so as to include a predetermined number of series connections and a predetermined number of parallel connections which are set for the light-emitting unit.

21. The manufacturing method according to claim 20, wherein,
in the forming step, the light-emitting units are formed by mounting the plurality of groups of light-emitting elements on a substrate in which openings are formed, based on positions of the openings,
in the arranging step, a lens array having support units is arranged as the lens array, and
the manufacturing method further comprises the step of positioning the substrate and the lens array by fitting the support units into the openings.

22. The manufacturing method according to claim 21, wherein
the openings are positioning holes formed on a diagonal line of the substrate, and
the support units are columnar members provided on the lens array according to the positions of the openings.

23. The manufacturing method according to claim 22, wherein
diameters along the diagonal line of the positioning holes become larger with increasing a distance from one end part of the diagonal line, and,
in the positioning step, the support units are fixed with respect to the openings such that a relative position between the light-emitting units and the lenses along the diagonal line can be changed in accordance with thermal expansion and thermal contraction.

24. The manufacturing method according to claim 21, further comprising the step of sealing the plurality of groups of light-emitting elements for each light-emitting unit by filling a resin in each of the light-emitting units.

25. The manufacturing method according to claim 24, further comprising the step of arranging sealing frames that respectively surround the plurality of groups of light-emitting elements on the substrate, based on the positions of the openings, wherein,
in the sealing step, the resin is filled in respective regions surrounded by the sealing frames on the substrate.

26. The manufacturing method according to claim 20, further comprising the step of positioning the substrate and the lens array by shifting the light-emitting units and the lenses from one another by a distance having a size according to thermal expansion coefficients of the substrate and the lens array such that positions of the light-emitting units relatively conform to positions of the lenses when the substrate and the lens array thermally expand by lighting the light-emitting units.

27. The manufacturing method according to claim 26, wherein
the substrate has a rectangular shape,
in the arranging step, end parts of the substrate and the lens array are fixed to a common housing such that a relative position between the light-emitting units and the lenses can be changed in accordance with thermal expansion and thermal contraction, and,
in the positioning step, adjacent two sides of the substrate and the end part of the lens array corresponding to the two sides are brought into contact with the housing, so that the substrate and the lens array are positioned.

28. The manufacturing method according to claim 26, wherein, in the forming step, in each of the light-emitting units,
LED elements are mounted on the substrate, as the light-emitting elements,
the LED elements are electrically connected to one another by wires, and
a sealing resin containing a phosphor is filled on the substrate to seal the LED elements.

29. The manufacturing method according to claim 26, wherein, in the forming step, in each of the light-emitting units, LED packages, each of which is configured by covering an upper surface and side surfaces of an LED element with a resin layer containing a phosphor, are flip-chip mounted on the substrate, as the light-emitting elements.
